(19) United States
(12) Patent Application Publication
(10) Pub. No.: US 2022/0199638 A1
(43) Pub. Date: Jun. 23, 2022

(54) SEMICONDUCTOR DEVICE

(71) Applicant: Kioxia Corporation, Tokyo (JP)

(72) Inventors: Kanae FUKUOKA, Mie (JP); Ayaha HACHISUGA, Yokkaichi (JP)

(73) Assignee: Kioxia Corporation, Tokyo (JP)

(21) Appl. No.: 17/304,024

(22) Filed: Jun. 14, 2021

(30) Foreign Application Priority Data
Dec. 18, 2020 (JP) 2020-209831

(51) Int. Cl. H01L 27/11575; H01L 21/768; H01L 27/11582; H01L 23/522

(52) U.S. Cl. CPC H01L 27/11575; H01L 23/5226; H01L 27/11582; H01L 21/76816

(57) ABSTRACT

According to one embodiment, a semiconductor device includes a stacked layer body including a first stacked portion in which first conductive layers are stacked, and which includes a stair-like first end, and a second stacked portion which is provided on an upper layer side of the first stacked portion, in which second conductive layers are stacked, and which includes a stair-like second end, a first stopper insulating layer covering at least a part of the first end, a second stopper insulating layer including a cover portion covering the second end and an extension portion extending from the cover portion, and a first contact penetrating through the extension portion and being connected to a corresponding one of the first conductive layers.

### CROSS-REFERENCE TO RELATED APPLICATIONS

This application is based upon and claims the benefit of priority from Japanese Patent Application No. 2020-209831, filed Dec. 18, 2020, the entire contents of which are incorporated herein by reference.

### FIELD

Embodiments described herein relate generally to a semiconductor device.

### BACKGROUND

In a three-dimensional nonvolatile memory in which a plurality of memory cells are stacked in a vertical direction, with an increase in the number of stacked layers, it becomes difficult to appropriately form contacts to be connected to the wiring extending from the memory cells.

### BRIEF DESCRIPTION OF THE DRAWINGS

FIG. 1 is a view schematically showing the overall arrangement configuration of a nonvolatile semiconductor memory device according to a first embodiment.

FIG. 2 is a cross-sectional view schematically showing the configuration of a memory region of the nonvolatile semiconductor memory device according to the first embodiment.

FIG. 3 is cross-sectional view schematically showing the configuration of a stairs region of the nonvolatile semiconductor memory device according to the first embodiment.

FIG. 4 is a plan view schematically showing an example of arrangement of pillar structures included in the memory region according to the first embodiment.

Each of FIG. 5A and FIG. 5B is a cross-sectional view schematically showing the detailed configuration of a memory cell section according to the first embodiment.

Each of FIG. 6A, FIG. 6B, FIG. 6C, FIG. 6D, FIG. 6E, FIG. 6F, FIG. 6G, FIG. 6H, FIG. 6I, FIG. 6J, FIG. 6K, FIG. 6L, FIG. 6M, and FIG. 6N is a cross-sectional view schematically showing a part of a manufacturing method of the nonvolatile semiconductor memory device according to the first embodiment.

Each of FIG. 7A, FIG. 7B, and FIG. 7C is a cross-sectional view schematically showing a part of a forming method of contact holes according to the first embodiment.

FIG. 8 is a cross-sectional view schematically showing the configuration of a stairs region of a nonvolatile semiconductor memory device according to a second embodiment.

Each of FIG. 9A, FIG. 9B, FIG. 9C, and FIG. 9D is a cross-sectional view schematically showing a part of a manufacturing method of the nonvolatile semiconductor memory device according to the second embodiment.

Each of FIG. 10A, FIG. 10B, and FIG. 10C is a cross-sectional view schematically showing a part of a forming method of contact holes according to the second embodiment.

### DETAILED DESCRIPTION

In general, according to one embodiment, a semiconductor device includes: a stacked layer body including a first stacked portion in which a plurality of first conductive layers are stacked to be apart from each other in a first direction, and which includes a stair-like first end, and a second stacked portion which is provided on an upper layer side of the first stacked portion, in which a plurality of second conductive layers are stacked to be apart from each other in the first direction, and which includes a stair-like second end; a plurality of pillar structures each of which includes a semiconductor layer extending in the first direction in the stacked layer body; a first stopper insulating layer covering at least a part of the first end; a second stopper insulating layer including a cover portion covering the second end and an extension portion extending from the cover portion, and being apart from the first stopper insulating layer; and a first contact penetrating through the extension portion of the second stopper insulating layer and being connected to a corresponding one of the first conductive layers.

Embodiments will be described hereinafter with reference to the accompanying drawings.

### Embodiment 1

FIG. 1 is a view schematically showing the overall arrangement configuration of a nonvolatile semiconductor memory device according to a first embodiment. It is to be noted that the X-direction, Y-direction, and Z-direction shown in FIG. 1 and figures subsequent to FIG. 1 are directions intersecting each other. More specifically, the X-direction, Y-direction, and Z-direction are directions perpendicular to each other.

As shown in FIG. 1, the nonvolatile semiconductor memory device according to this embodiment includes a memory region 100, stairs region 200, and peripheral circuit region 300 and these memory region 100, stairs region 200, and peripheral circuit region 300 are arranged on the same semiconductor substrate.

In the memory region 100, a NAND-type nonvolatile memory cell array having a three-dimensional structure is provided. More specifically, a NAND string is constituted of a plurality of memory cells and a plurality of select transistors arranged in the direction (Z-direction, first direction) perpendicular to the principal plane of the semiconductor substrate, and a plurality of NAND strings are arranged in an array form in parallel with the X-Y plane (plane perpendicular to the Z-direction).

The stairs region 200 is provided adjacently to the memory region 100. As will be described later, a plurality of contacts configured to send signals to the memory region 100 are connected to an end of the stairs region 200.

Peripheral circuits for the memory cell array provided in the memory region 100 are provided in the peripheral circuit region 300.

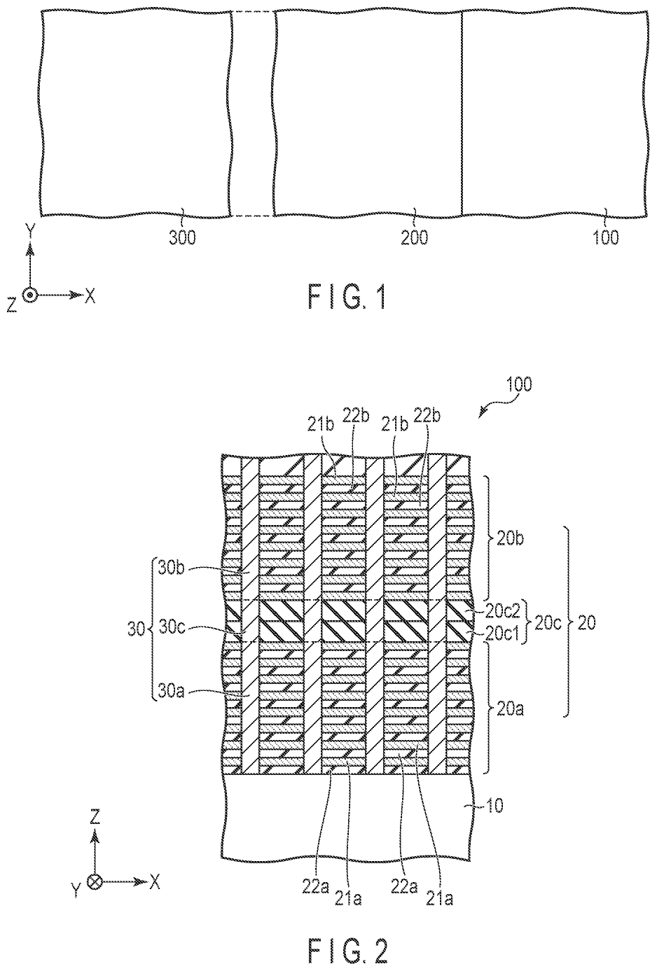

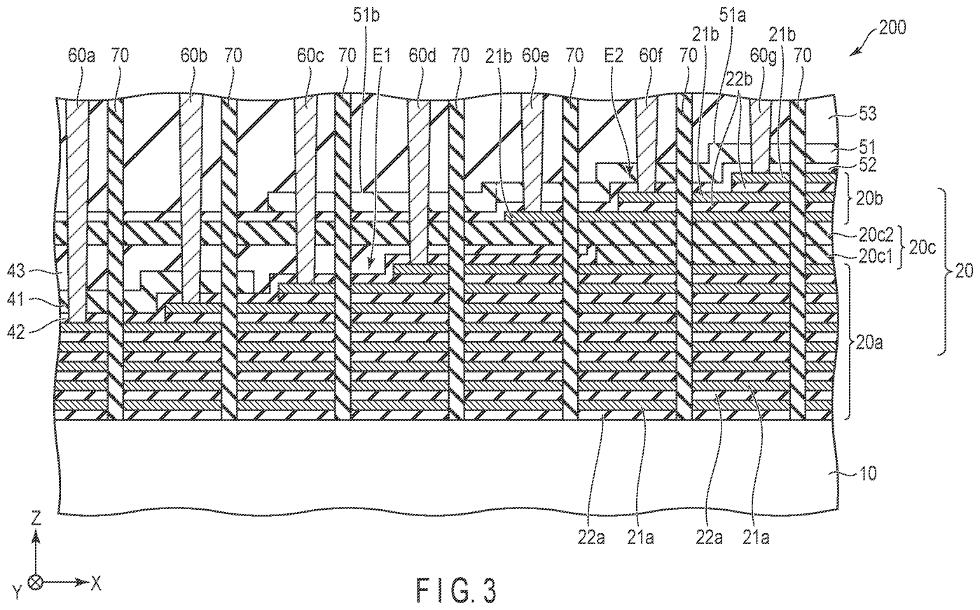

FIG. 2 and FIG. 3 are views schematically showing the configurations of the memory region 100 and stairs region 200, respectively, and show cross sections in a direction parallel to the X-Z plane.

In the memory region 100 and stairs region 200, a stacked layer body 20 is provided on the semiconductor substrate 10. The stacked layer body 20 is provided in such a manner as to be continuous from the memory region 100 to the stairs region 200.

The stacked layer body 20 includes a first stacked portion 20a, second stacked portion 20b provided on the upper layer side of the first stacked portion 20a, and intermediate portion 20c provided between the first stacked portion 20a and second stacked portion 20b.

The first stacked portion 20a has a structure in which a plurality of first conductive layers 21a are stacked in such a manner as to be apart from each other in the Z-direction, and second stacked portion 20b has a structure in which a plurality of second conductive layers 21b are stacked in such a manner as to be apart from each other in the Z-direction. More specifically, the first stacked portion 20a has a structure in which a plurality of first conductive layers 21a and a plurality of first insulating layers 22a are alternately stacked in the Z-direction, and second stacked portion 20b has a structure in which a plurality of second conductive layers 21b and a plurality of second insulating layers 22b are alternately stacked in the Z-direction. It is to be noted that in the subsequent descriptions, each of the first conductive layer 21a and second conductive layer 21b is simply referred to as a conductive layer 21 in some cases, and each of the first insulating layer 22a and second insulating layer 22b is simply referred to as an insulating layer 22 in some cases.

The first stacked portion 20a includes a stair-like first end E1 defined by a plurality of steps, and second stacked portion 20b includes a stair-like second end E2 defined by a plurality of steps. One step is defined by a rising section approximately parallel to the Z-direction, and terrace section (terrace surface) extending from an upper end of the rising section approximately in parallel with the X-Y plane. Each step is constituted of one conductive layer 21 and one insulating layer 22. In this description, the direction in which the terrace section (terrace surface) faces is defined as the upper (upward) direction.

The conductive layer 21 is a layer configured to function as a word line or select gate line, and insulating layer 22 is a layer configured to separate and insulate conductive layers 21 from each other. The conductive layer 21 is formed of a metallic material such as tungsten (W) or the like, and insulating layer 22 is formed of an insulating material such as silicon oxide or the like.

The intermediate portion 20c includes a lower layer portion 20c1 and upper layer portion 20c2, and is formed of an intermediate insulating layer. Further, as shown in FIG. 3, the intermediate portion 20c includes a first portion provided between the first stacked portion 20a and second stacked portion 20b, second portion extending from the first portion to an area beneath an extension portion 51b of a second stopper insulating layer 51 to be described later, and third portion extending from the second portion to a direction opposite to the direction in which the first portion is provided. The intermediate portion 20c is formed of a material different from a material for the first stopper insulating layer 41 to be described later and material for the second stopper insulating layer 51. More specifically, the intermediate insulating layer is formed of silicon oxide, and the thickness of the intermediate insulating layer is greater than the thickness of the first insulating layer 22a and thickness of the second insulating layer 22b.

In the memory region 100, a plurality of pillar structures 30 each of which includes semiconductor layer extending in the Z-direction in the stacked layer body 20 are provided.

The pillar structure 30 includes a first pillar portion 30a, second pillar portion 30b, and intermediate pillar portion 30c interposed between the first pillar portion 30a and second pillar portion 30b. The first pillar portion 30a is surrounded by the first stacked portion 20a, second pillar portion 30b is surrounded by the second stacked portion 20b, and intermediate pillar portion 30c is surrounded by the intermediate portion 20c.

A NAND string is constituted of the pillar structure 30 and the plurality of conductive layers 21 surrounding the pillar structure 30. The NAND string includes a plurality of memory cells connected in series, upper select transistors (drain-side select transistors) provided on the upper layer side of the plurality of memory cells and connected in series to the plurality of memory cells, and lower select transistors (source-side select transistors) provided on the lower layer side of the plurality of memory cells and connected in series to the plurality of memory cells.

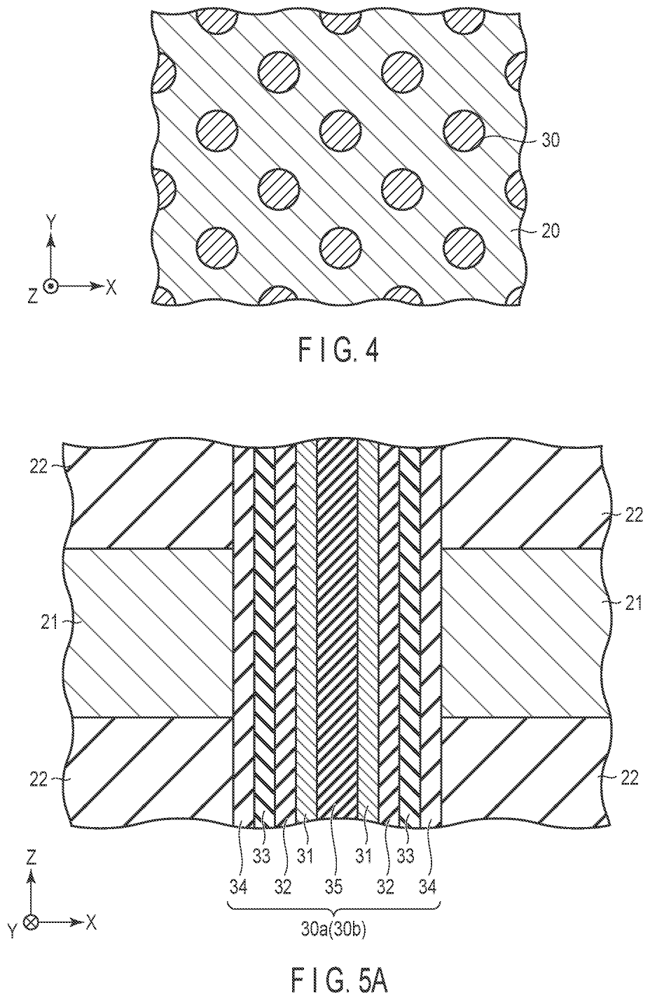

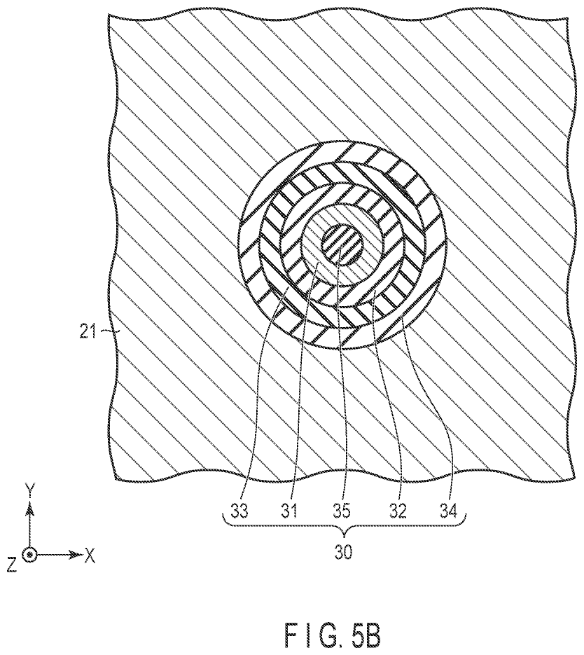

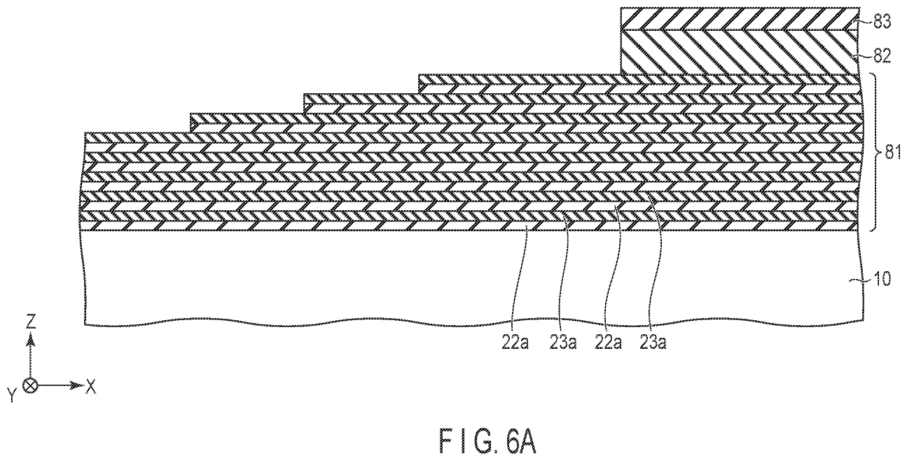

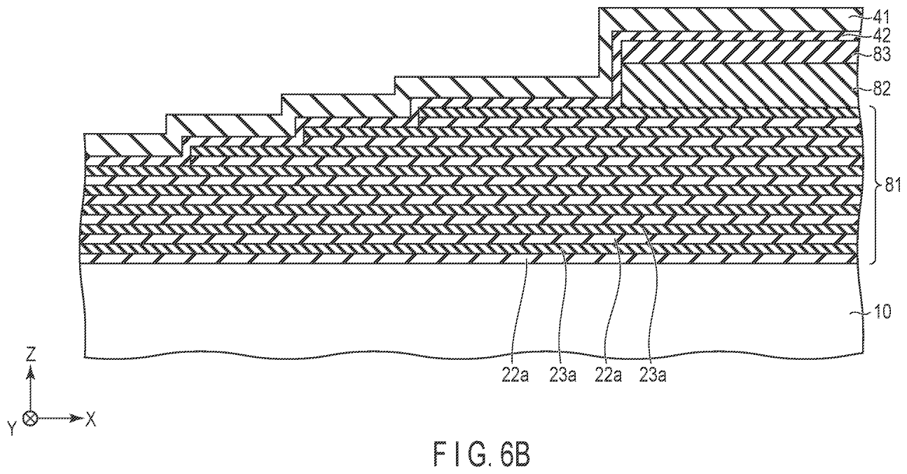

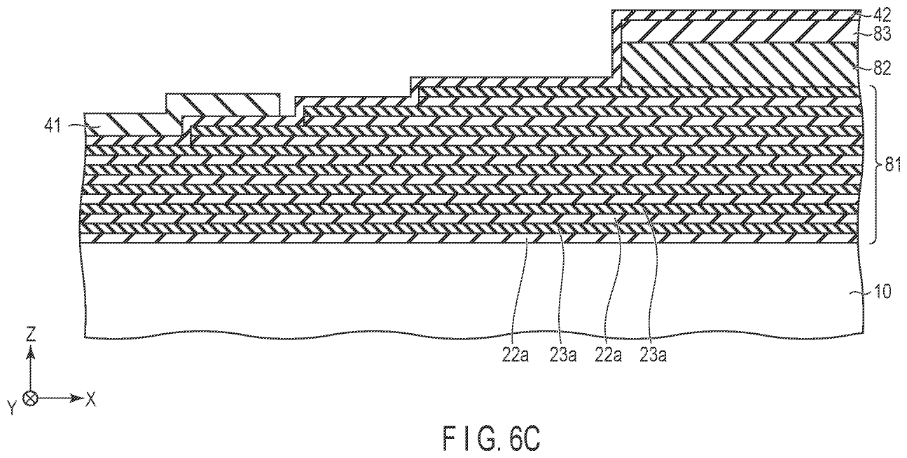

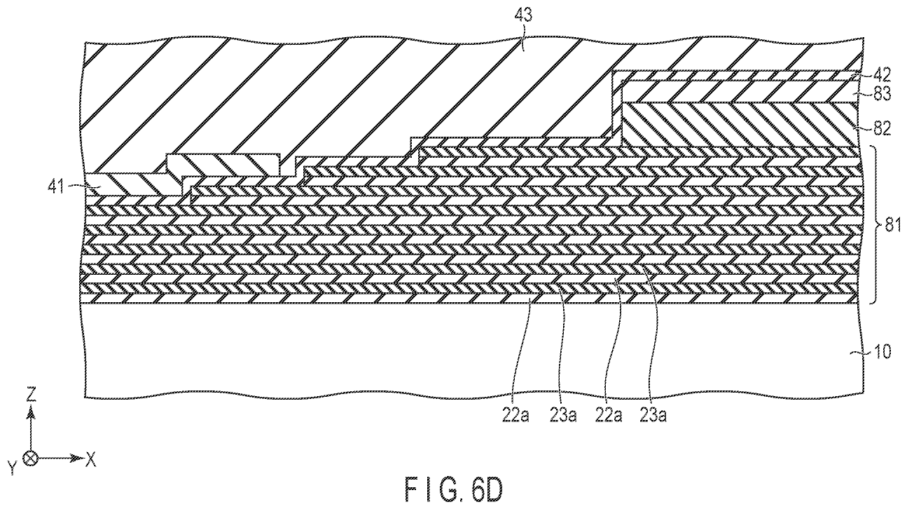

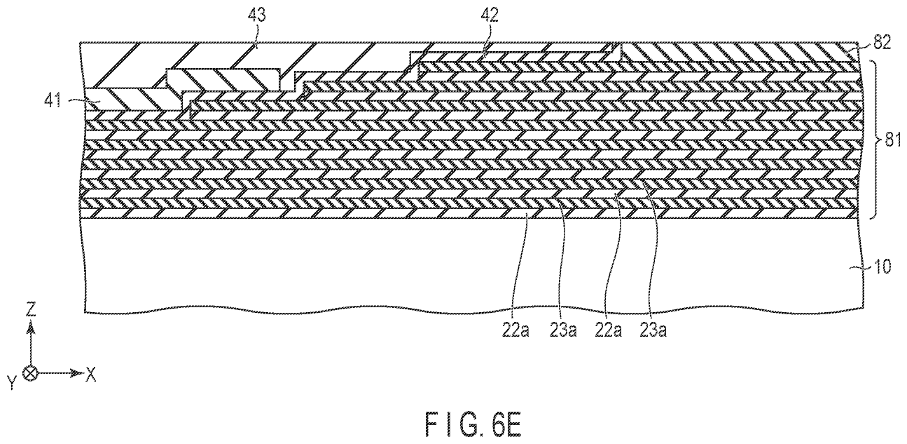

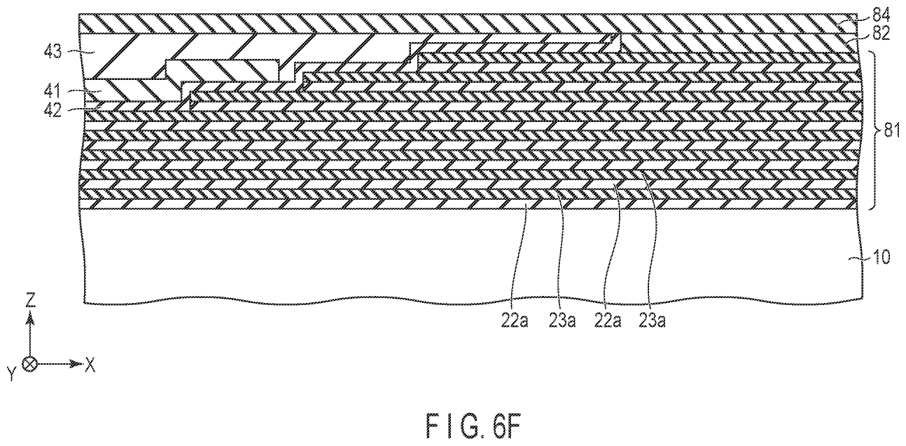

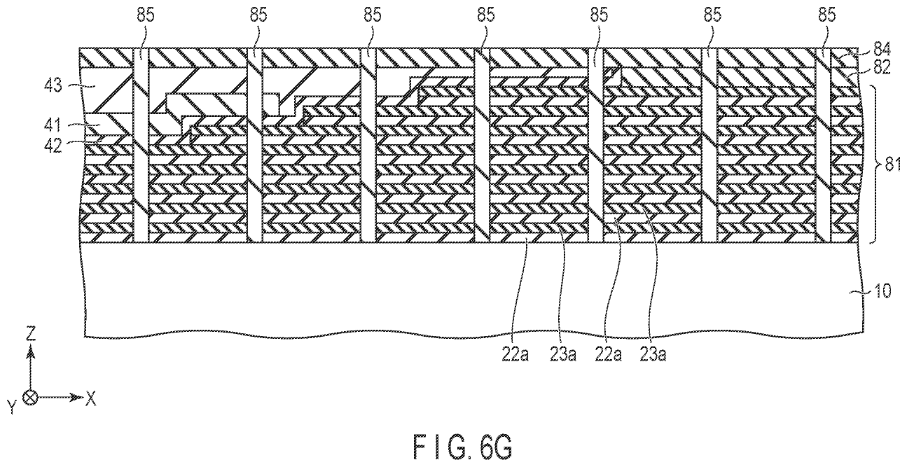

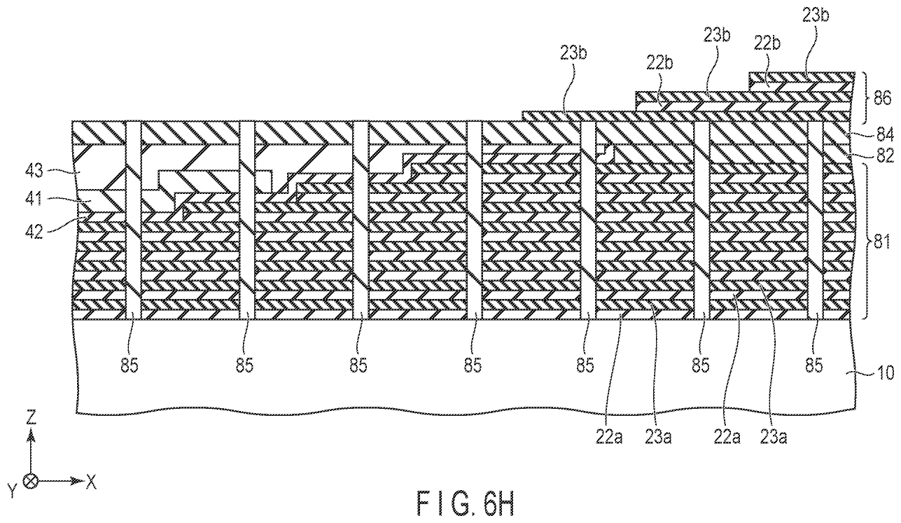

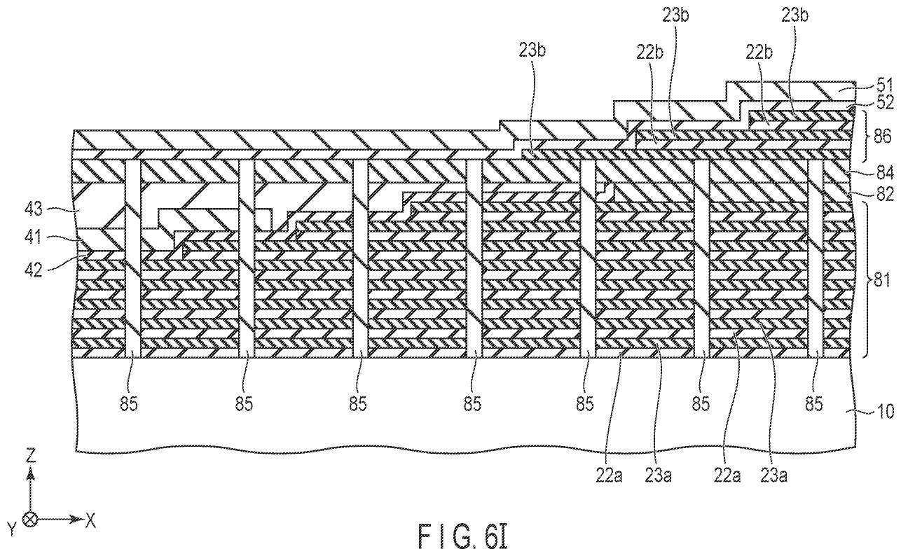

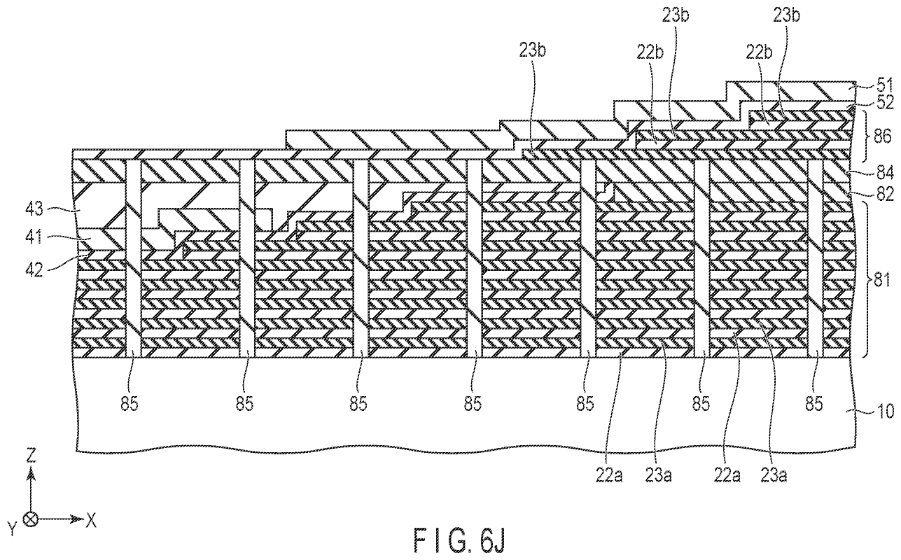

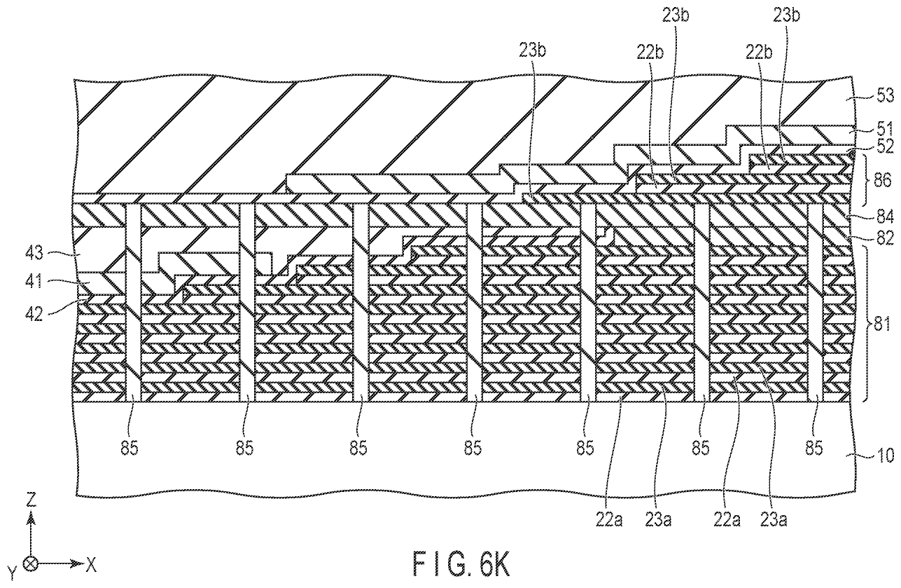

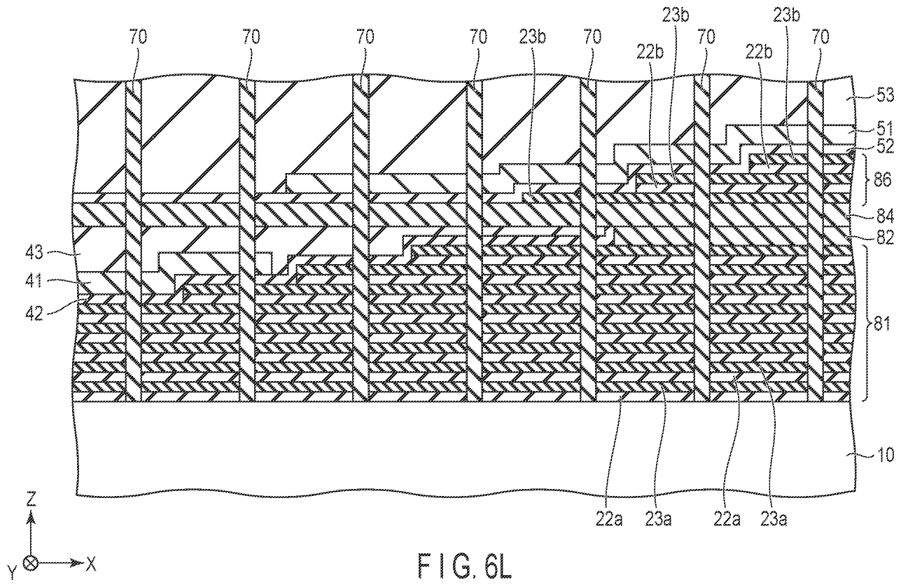

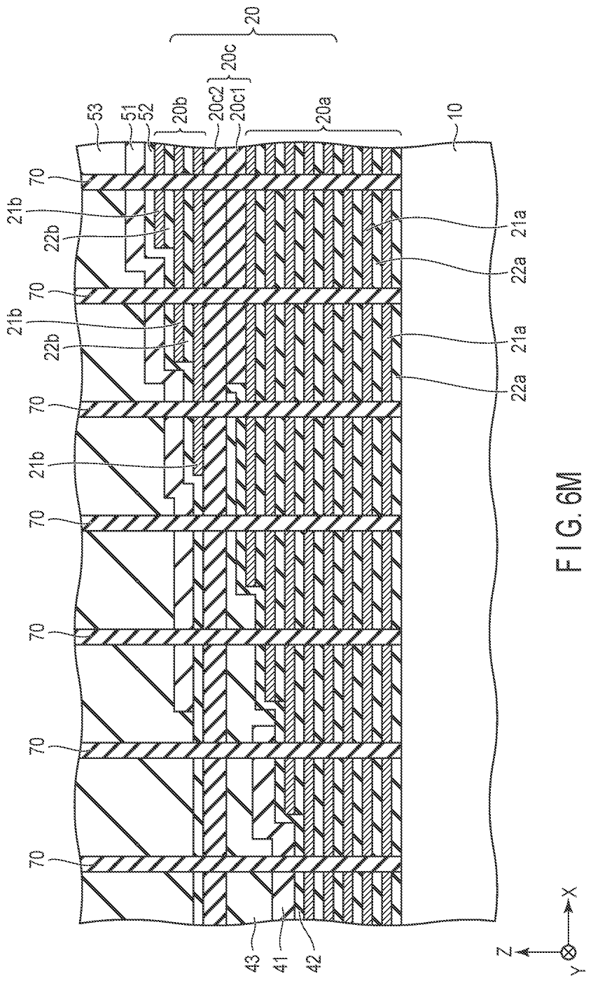

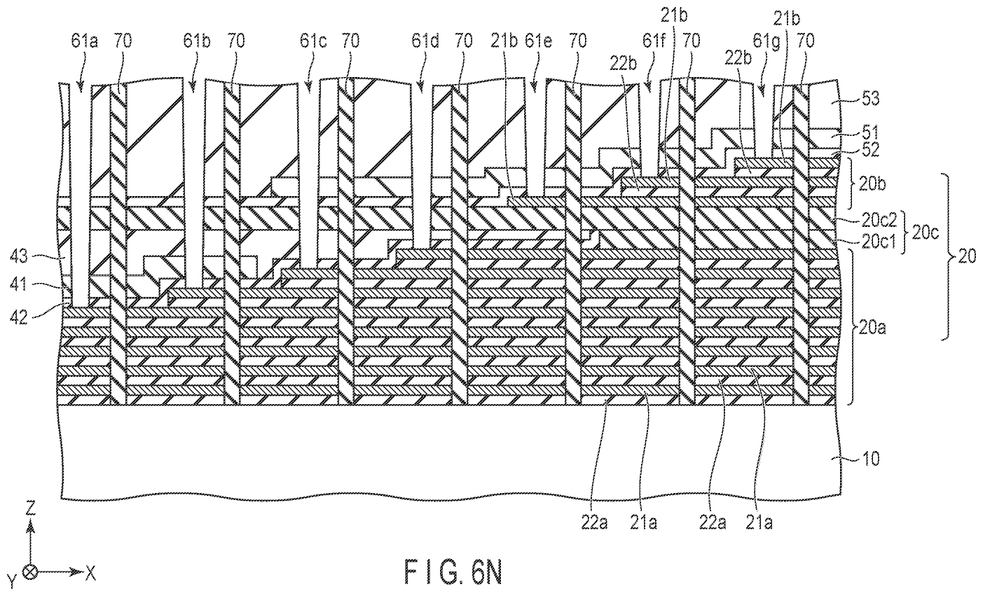

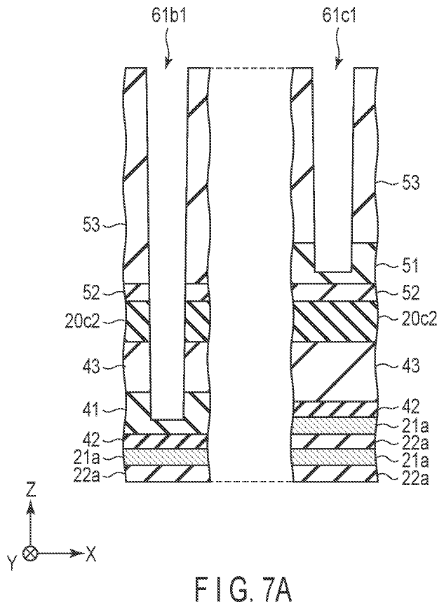

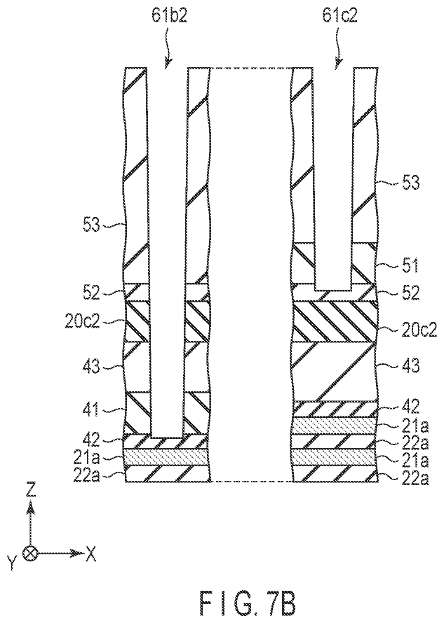

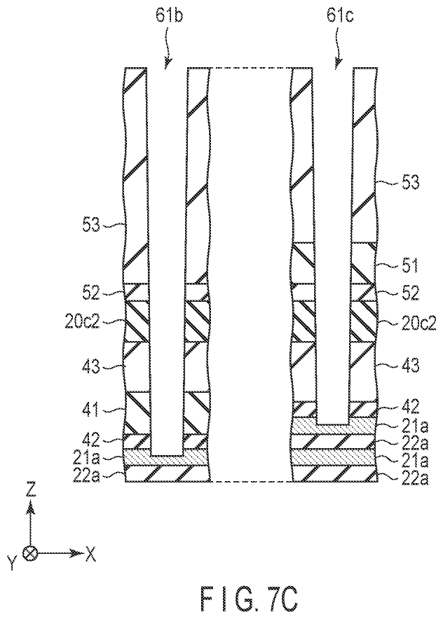

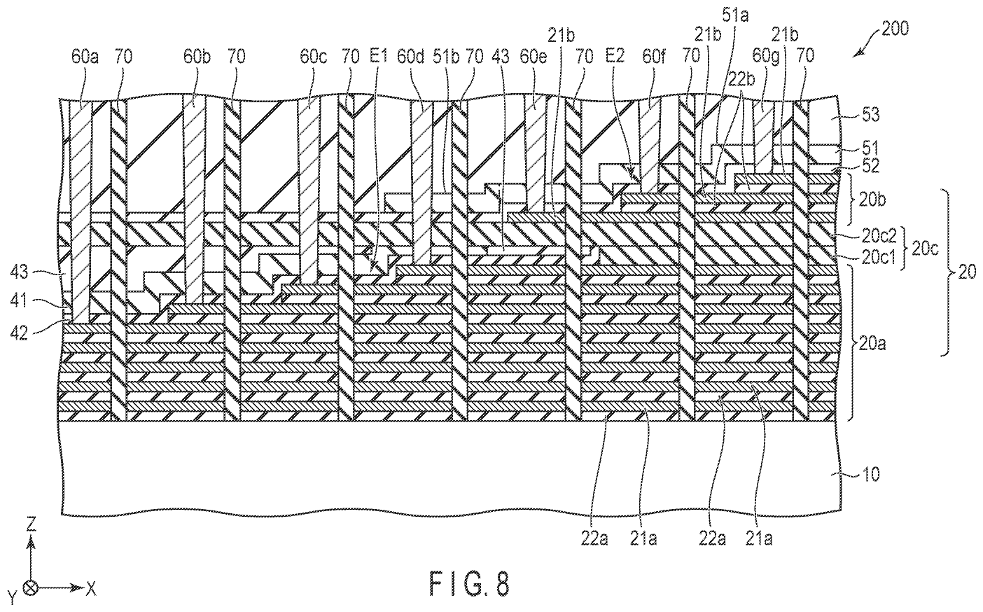

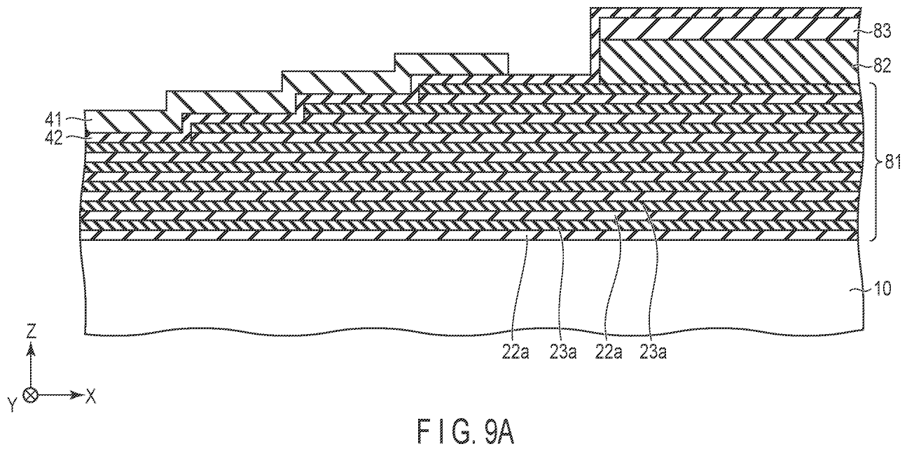

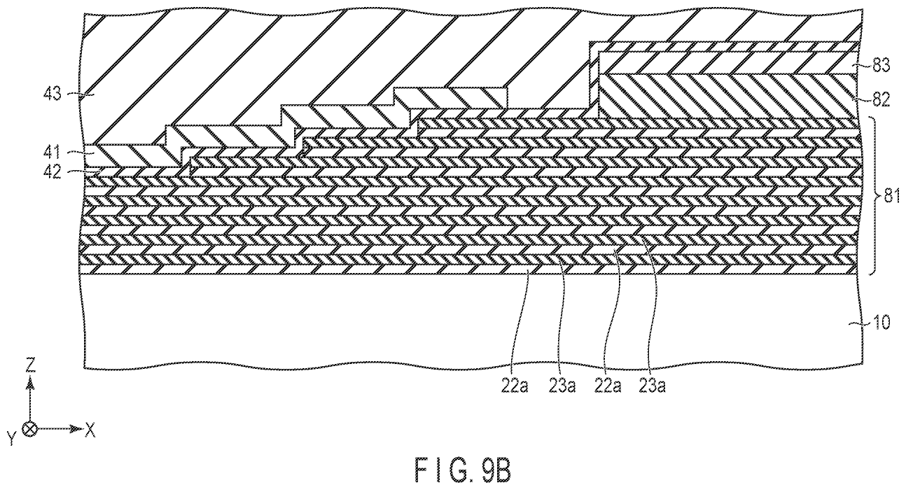

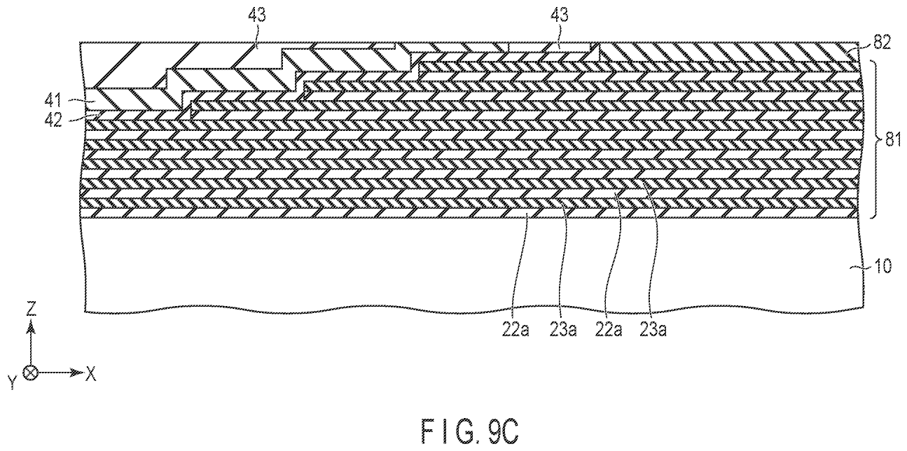

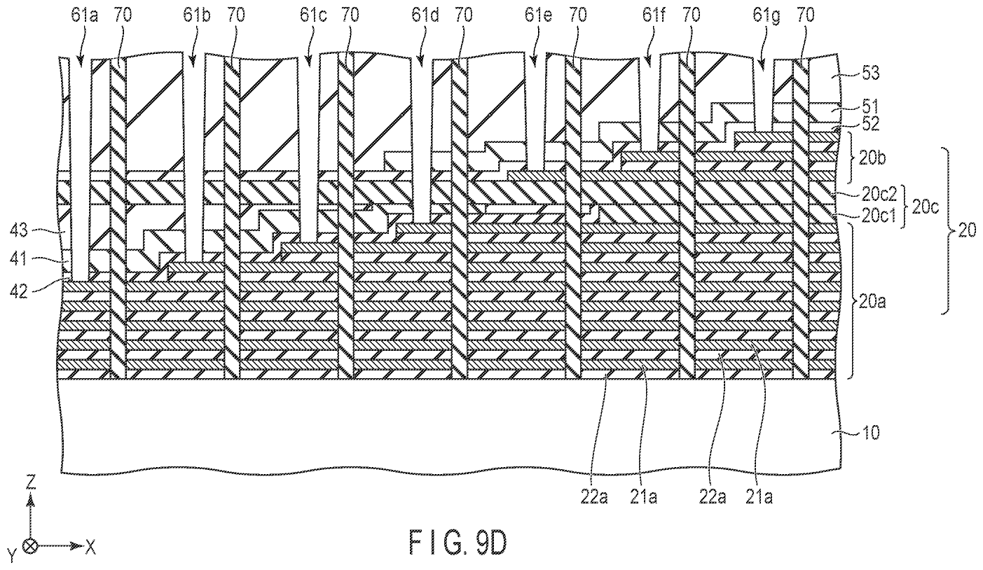

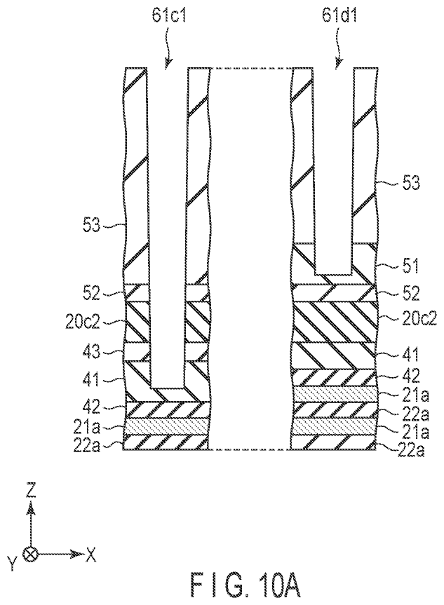

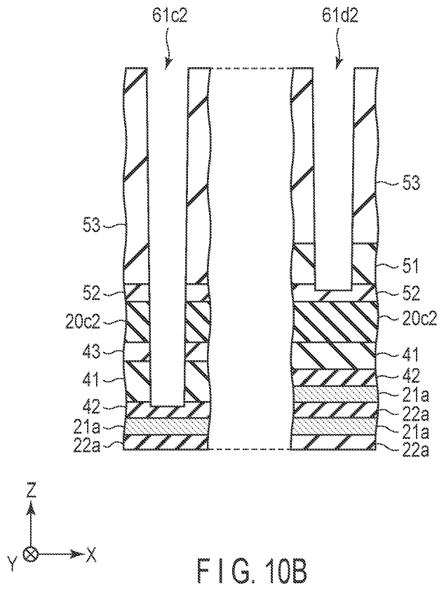

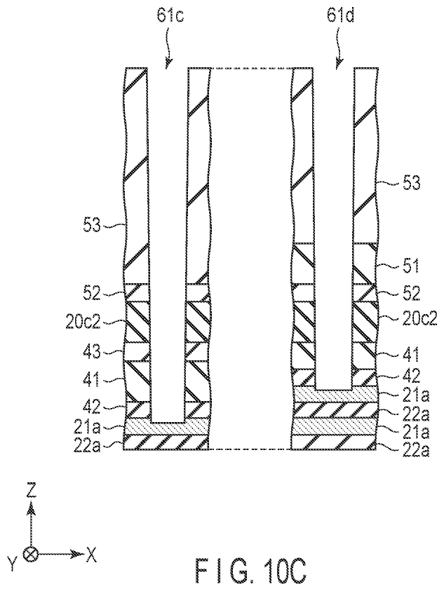

FIG. 4 is a plan view schematically showing an example of arrangement of the pillar structures 30 included in the memory region 100. As shown in FIG. 4, the plurality of pillar structures 30 are arranged in parallel with the X-Y plane, and each pillar structure 30 is surrounded by the stacked layer body 20.

Each of FIG. 5A and FIG. 5B is a cross-sectional view schematically showing the detailed configuration of a memory cell section constituted of the conductive layers 21 and pillar structure 30. FIG. 5A is a cross-sectional view in the direction parallel to the Z-direction, and FIG. 5B is a cross-sectional view in the direction perpendicular to the Z-direction.

In the memory cell section, the pillar structure 30 includes a semiconductor layer 31, tunnel insulating layer 32, charge storage layer 33, block insulating layer 34, and core insulating layer 35. Each of the semiconductor layer 31, tunnel insulating layer 32, charge storage layer 33, and block insulating layer 34 has a cylindrical shape, and core insulating layer 35 has a columnar shape. More specifically, the semiconductor layer 31 surrounds the side surface of the core insulating layer 35, tunnel insulating layer 32 surrounds the side surface of the semiconductor layer 31, charge storage layer 33 surrounds the side surface of the tunnel insulating layer 32, and block insulating layer 34 surrounds the side surface of the charge storage layer 33. For example, the semiconductor layer 31 is formed of silicon, tunnel insulating layer 32 is formed of silicon oxide, charge storage layer 33 is formed of silicon nitride, block insulating layer 34 is formed of silicon oxide, and core insulating layer 35 is formed of silicon oxide.

The conductive layer 21 surrounding the pillar structure 30 functions as a gate electrode, and a memory cell is constituted of a part of the conductive layer 21 functioning as the gate electrode and a part of the pillar structure 30 surrounded by the conductive layer 21.

It is to be noted that the configuration of the select transistor section is also identical to the configuration of the memory cell section shown in FIG. 5A and FIG. 5B. In the select transistor section, the tunnel insulating layer 32, charge storage layer 33, and block insulating layer 34 function as a gate insulating layer.

In the stairs region 200 shown in FIG. 3, as already described previously, the first stacked portion 20a and second stacked portion 20b of the stacked layer body 20 include the first end E1, and second end E2, respectively. These first end E1 and second end E2 are covered with at least any one of the first stopper insulating layer 41 and second stopper insulating layer 51 which are apart from each other.

In the example shown in FIG. 3, a part of the first end E1 is covered with the first stopper insulating layer 41. In other words, the first stopper insulating layer 41 is provided along a part of the first end E1. The first stopper insulating layer 41 is a layer configured to function as an etching stopper at the time when contact holes to be described later are formed, and is formed of silicon nitride.

On the lower layer side of the first stopper insulating layer 41, a first lower insulating layer 42 is provided. In the example shown in FIG. 3, the first lower insulating layer 42 includes a portion extending from a portion positioned under the first stopper insulating layer 41. That is, the first lower insulating layer 42 includes a first portion provided between the first stacked portion 20a and first stopper insulating layer 41 and not provided beneath the extension portion 51b (to be described later) of the second stopper insulating layer 51, and second portion extending from the first portion to the area beneath the extension portion 51b of the second stopper insulating layer 51. The first lower insulating layer 42 is formed of a material different from the material for the first stopper insulating layer 41 and material for the second stopper insulating layer 51. More specifically, the first lower insulating layer 42 is formed of silicon oxide.

The first stopper insulating layer 41 is covered with a first interlayer insulating layer 43. The first interlayer insulating layer 43 is formed of a material different from the material for the first stopper insulating layer 41 and material for the second stopper insulating layer 51. More specifically, the first interlayer insulating layer 43 is formed of silicon oxide.

The second end E2 of the second stacked portion 20b is covered with the second stopper insulating layer 51. In other words, the second stopper insulating layer 51 is provided along the second end E2. This second stopper insulating layer 51 includes a cover portion 51a covering the second end E2, and extension portion 51b extending from the cover portion 51a. That is, the second stopper insulating layer 51 includes the extension portion 51b extending toward a part above the first end E1 and overlapping a part of the first end E1 when viewed from the Z-direction. The second stopper insulating layer 51 is a layer configured to function as an etching stopper at the time when contact holes to be described later are formed, and is formed of silicon nitride.

On the lower layer side of the second stopper insulating layer 51, a second lower insulating layer 52 is provided. In the example shown in FIG. 3, the second lower insulating layer 52 includes also a portion extending from a portion thereof positioned under the second stopper insulating layer 51. That is, the second lower insulating layer 52 includes a first portion provided between the second stacked portion 20b and cover portion 51a of the second stopper insulating layer, second portion extending from the first portion to an area under the extension portion 51b of the second stopper insulating layer 51, and third portion extending from the second portion to a direction opposite to the direction in which the first portion is provided. The second lower insulating layer 52 is formed of a material different from the material for the first stopper insulating layer 41 and material for the second stopper insulating layer 51. More specifically, the second lower insulating layer 52 is formed of silicon oxide.

The second stopper insulating layer 51 is covered with a second interlayer insulating layer 53. The second interlayer insulating layer 53 is formed of a material different from the material for the first stopper insulating layer 41 and material for the second stopper insulating layer 51. More specifically, the second interlayer insulating layer 53 is formed of silicon oxide.

At the end E1 of the first stacked portion 20a, contacts 60a to 60d are respectively connected to the first conductive layers 21a. Further, at the end E2 of the second stacked portion 20b, contacts 60e to 60g are respectively connected to the second conductive layers 21b.

More specifically, each of the contacts (second contacts) 60a and 60b penetrates through the second interlayer insulating layer 53, aforementioned third portion of the second lower insulating layer 52, aforementioned third portion of the intermediate portion (intermediate insulating layer) 20c of the stacked layer body 20, first interlayer insulating layer 43, first stopper insulating layer 41, and aforementioned first portion of the first lower insulating layer 42, and is connected to the corresponding first conductive layer 21a.

Each of the contacts (first contacts) 60c and 60d penetrates through the second interlayer insulating layer 53, extension portion 51b of the second stopper insulating layer 51, aforementioned second portion of the second lower insulating layer 52, aforementioned second portion of the intermediate portion (intermediate insulating layer) 20c of the stacked layer body 20, first interlayer insulating layer 43, and aforementioned second portion of the first lower insulating layer 42, and is connected to the corresponding first conductive layer 21a.

Each of the contacts (third contacts) 60e, 60f, and 60g penetrates through the second interlayer insulating layer 53, second stopper insulating layer 51, and aforementioned first portion of the second lower insulating layer 52, and is connected to the corresponding second conductive layer 21b.

As can be seen from the above description, in this embodiment, among the contacts 60a to 60d respectively connected to the first conductive layers 21a, the contacts 60a and 60b penetrate through the first stopper insulating layer 41 without penetrating through the second stopper insulating layer 51, and are respectively connected to the corresponding first conductive layers 21a. The contacts 60c and 60d penetrate through the second stopper insulating layer 51, and are respectively connected to the corresponding first conductive layers 21a without penetrating through the first stopper insulating layer 41. The contact 60d is connected to the first conductive layer 21a of the uppermost layer of the first stacked portion 20a, and contact 60c is connected to the first conductive layer 21a of the second layer from the uppermost layer of the first stacked portion 20a.

Further, in the stairs region 200, a plurality of support structures 70 penetrating through the stacked layer body 20 and the like are provided. This support structure 70 is configured to fulfill a supporting function in the replacement process to be described later.

Next, a manufacturing method of the nonvolatile semiconductor memory device according to this embodiment will be described below.

Each of FIGS. 6A to 6N is a cross-sectional view schematically showing a manufacturing method of the nonvolatile semiconductor memory device according to this embodiment.

First, as shown in FIG. 6A, a stacked layer film 81 is formed on the semiconductor substrate 10, silicon oxide layer 82 is formed on the stacked layer film 81, and silicon nitride layer 83 is formed on the silicon oxide layer 82. The stacked layer film 81 has a structure in which a plurality of insulating layers 22a and a plurality of sacrificial layers 23a are alternately stacked in the Z-direction. The insulating layer 22a is formed of silicon oxide, and sacrificial layer 23a is formed of silicon nitride. Subsequently, by subjecting the stacked layer film 81, silicon oxide layer 82, and silicon nitride layer 83 to patterning to thereby form a stair-like structure.

Next, as shown in FIG. 6B, a silicon oxide layer is formed as the first lower insulating layer 42 in such a manner as to cover the structure obtained by the step of FIG. 6A and, furthermore, a silicon nitride layer is formed as the first stopper insulating layer 41.

Next, as shown in FIG. 6C, the first stopper insulating layer 41 is subjected to patterning by RIE (reactive ion etching).

Next, as shown in FIG. 6D, a silicon oxide layer is formed as the first interlayer insulating layer 43 in such a manner as to cover the structure obtained by the step of FIG. 6C.

Next, as shown in FIG. 6E, planarization processing is carried out by CMP (chemical mechanical polishing) and etch back. By this planarization processing, the silicon nitride layer 83 is removed, and the thickness of the first interlayer insulating layer 43 and thickness of the silicon oxide layer 82 are reduced.

Next, as shown in FIG. 6F, a silicon oxide layer 84 is formed in such a manner as to cover the structure obtained by the step of FIG. 6E.

Next, as shown in FIG. 6G, a plurality of holes are formed in the structure obtained by the step of FIG. 6F, and these holes are filled with a predetermined material, whereby a plurality of predetermined material layer patterns 85 are formed.

Next, as shown in FIG. 6H, a stacked layer film 86 is formed on the structure obtained by the step of FIG. 6G. The stacked layer film 86 has a structure in which a plurality of insulating layers 22b and a plurality of sacrificial layers 23b are alternately stacked in the Z direction. The insulating layer 22b is formed of silicon oxide, and sacrificial layer 23b is formed of silicon nitride. Subsequently, this stacked layer film 86 is subjected to patterning, thereby forming a stair-like structure.

Next, as shown in FIG. 6I, a silicon oxide layer is formed as the second lower insulating layer 52 in such a manner as to cover the structure obtained by the step of FIG. 6H and, furthermore, a silicon nitride layer is formed as the second stopper insulating layer 51.

Next, as shown in FIG. 6J, the second stopper insulating layer 51 is subjected to patterning by RIE.

Next, as shown in FIG. 6K, a silicon oxide layer is formed as the second interlayer insulating layer 53 in such a manner as to cover the structure obtained by the step of FIG. 6J.

Next as shown in FIG. 6L, a plurality of holes are formed in the structure obtained by the step of FIG. 6K. More specifically, a plurality of preliminary holes reaching the plurality of predetermined material layer patterns 85 are formed and, furthermore, the predetermined material layers are removed, whereby a plurality of holes extending from the top surface of the second interlayer insulating layer 53 to the top surface of the semiconductor substrate 10 are formed. Furthermore, the plurality of holes are filled with silicon oxide, whereby the plurality of support structures 70 are formed.

Next, as shown in FIG. 6M, a replacement process is carried out. More specifically, first, a slit pattern (not shown) is formed in the structure obtained by the step of FIG. 6L, and the first sacrificial layer 23a and second sacrificial layer 23b are removed by selective etching to be carried out through the slit pattern, whereby a plurality of spaces are formed. At this time, it is possible to support the first insulating layers 22a and second insulating layers 22b by the support structures 70. Subsequently, the spaces are filled with a metallic material such as tungsten (W) or the like through the slit pattern, whereby the first conductive layers 21a and second conductive layers 21b are formed. In this way, the stacked layer body 20 including the first stacked portion 20a, second stacked portion 20b, and intermediate portion 20c is formed. Thereafter, the slit pattern is filled with an insulating material or a stacked structure of the insulating material and electrically conductive material.

Next, as shown in FIG. 6N, the plurality of contact holes 61a to 61g are formed in the structure obtained by the step of FIG. 6M by RIE.

Each of FIGS. 7A to 7C is a cross-sectional view schematically showing a forming method of the contact holes 61a to 61g. It is to be noted that in FIGS. 7A to 7C, only the contact holes 61b and 61c are shown.

First, as shown in FIG. 7A, the contact holes 61b1 and 61c1 are respectively formed up to the midway position of the first stopper insulating layer 41 and midway position of the second stopper insulating layer 51.

Subsequently, as shown in FIG. 7B, the contact holes 61b2 and 61c2 are respectively formed up to the midway position of the first lower insulating layer 42 and midway position of the second lower insulating layer 52.

Thereafter, as shown in FIG. 7C, the contact holes 61b and 61c are respectively formed in such a manner as to reach the corresponding first conductive layers 21a. Thereby, as shown in FIG. 6N, the contact holes 61a to 61g are formed.

After the step of FIG. 6N, the contact holes 61a to 61g are filled with a metallic material, whereby the contacts 60a to 60g as shown in FIG. 3 are formed.

As described above, in this embodiment, the second stopper insulating layer 51 includes the extension portion 51b and, among the contacts 60a to 60d to be respectively connected to the corresponding first conductive layers 21a, the contacts 60c and 60d each penetrate through the extension portion 51b of the second stopper insulating layer 51 to thereby be connected to the corresponding first conductive layers 21a. By virtue of such a configuration, in this embodiment, it becomes possible to appropriately form the contacts 60a to 60g as will be described below.

As can be seen from FIG. 3, there are considerable differences in height between the contacts 60a to 60g. For this reason, there are also considerable differences in depth between the contact holes 61a to 61g. In order to form the contact holes 61a to 61g largely different from each other in depth by a common etching step, the first stopper insulating layer 41 and second stopper insulating layer 51 functioning as etching stoppers are provided. However, even by providing the first stopper insulating layer 41 and second stopper insulating layer 51 functioning as described above, it is not easy to form the contact holes 61a to 61g largely different from each other in depth by a common etching step.

Assuming here that the second stopper insulating layer 51 includes no extension portion 51b, then, for example, a configuration contrived in such a manner that the first stopper insulating layer 41 is extended further, and the contact holes 61c and 61d are made to penetrate through the first stopper insulating layer 41 is adoptable. However, when such a configuration is used, the thickness of the first stopper insulating layer 41 becomes less, and there is a possibility of the first stopper insulating layer 41 becoming unable to sufficiently fulfill the function as the etching stopper.

More specifically, when the above-mentioned configuration is adopted, when the etch back processing is carried out in the step of FIG. 6E, the part of the first stopper insulating layer 41 positioned on the uppermost layer side (part positioned on the terrace of the uppermost step of the first stacked portion 20a) is also etched, whereby the thickness of the first stopper insulating layer 41 is reduced at this part. For this reason, when the contact holes 61a to 61g are formed in the step of FIG. 6N, there is a possibility of the first stopper insulating layer 41 being unable to sufficiently fulfill the function as the etching stopper, and further there is a possibility of the contact hole 61d penetrating through the corresponding first conductive layer 21a and reaching the first conductive layer 21a on the lower layer side. As a result, there is a possibility of the contact 60d reaching the first conductive layer 21a on the lower side of the corresponding first conductive layer 21a.

In this embodiment, the first stopper insulating layer 41 does not extend to the uppermost step of the first stacked portion 20a, and hence at the time of the etch back processing of FIG. 6E, the first stopper insulating layer 41 is never etched, and the thickness of the first stopper insulating layer 41 is never reduced. In this embodiment, the second stopper insulating layer 51 includes the extension portion 51b, and hence the extension portion 51b of the second stopper insulating layer 51 functions as the etching stopper for the contact holes 61c and 61d in place of the first stopper insulating layer 41. This extension portion 51b has a sufficient thickness when the contact holes 61c and 61d are formed in the step of FIG. 6N, and can sufficiently fulfill the function as the etching stopper.

Accordingly, in this embodiment, it is possible to prevent the problem described above from occurring, and it becomes possible to appropriately form the contacts.

It is to be noted that although in the above description, the description has been given of the case where among the contacts 60a to 60d to be connected to the corresponding first conductive layers 21a, the contacts 60c and 60d penetrate through the second stopper insulating layer 51 and are connected to the corresponding first conductive layers 21a without penetrating through the first stopper insulating layer 41, this embodiment is not limited to this. For example, the patterns of the first stopper insulating layer 41 and second stopper insulating layer 51 may be changed and, among the contacts 60a to 60d to be connected to the corresponding first conductive layers 21a, only the contact 60d may penetrate through the second stopper insulating layer 51 and may be connected to the corresponding first conductive layer 21a without penetrating through the first stopper insulating layer 41. Further, the configuration may also be contrived in such a manner that three or more contacts 60 to be connected to the first conductive layers 21a on the upper layer side of the first stacked portion 20a penetrate through the second stopper insulating layer 51 and are connected to the corresponding first conductive layers 21a without penetrating through the first stopper insulating layer 41.

### Embodiment 2

Next, a second embodiment will be described below. It is to be noted that the fundamental items are identical to the first embodiment, and descriptions of the items already described in the first embodiment are omitted.

FIG. 8 is a cross-sectional view schematically showing the configuration of a stairs region 200 of a nonvolatile semiconductor memory device according to a second embodiment, and shows a cross section in the direction parallel to the X-Z plane.

In this embodiment too, as in the case of the first embodiment, the second stopper insulating layer 51 includes the cover portion 51a covering the second end E2, and extension portion 51b extending from the cover portion 51a.

Further, in this embodiment, a part of the first stopper insulating layer 41 is present beneath the extension portion 51b of the second stopper insulating layer 51. That is, when viewed from the Z-direction, the extension portion 51b of the second stopper insulating layer 51 overlaps the first stopper insulating layer 41. For this reason, in this embodiment, the contact 60d penetrates through the extension portion 51b of the second stopper insulating layer 51 and first stopper insulating layer 41, and is connected to the corresponding first conductive layer 21a. That is, the contact 60d is connected to the first conductive layer 21a of the uppermost layer of the first stacked portion 20a.

Further, in this embodiment, the thickness of the first stopper insulating layer 41 is reduced at the uppermost part positioned on the uppermost side thereof which is also the part positioned on the terrace of the uppermost step of the first stacked portion 20a.

Further, in this embodiment, the first interlayer insulating layer 43 covers the first stopper insulating layer 41 except the uppermost part of the first stopper insulating layer 41, and contact (first contact) 60d is connected to the first conductive layer 21a not through the first interlayer insulating layer 43 but through the uppermost part of the first stopper insulating layer 41.

Next, a manufacturing method of the nonvolatile semiconductor memory device according to this embodiment will be described below with reference to FIGS. 9A to 9D. The fundamental manufacturing method is identical to the manufacturing method of the above-described first embodiment, and descriptions of the items already described in the first embodiment are omitted.

After carrying out the steps identical to the steps of FIG. 6A and FIG. 6B of the first embodiment, the first stopper insulating layer 41 is subjected to patterning by the step identical to the step of FIG. 6C of the first embodiment as shown in FIG. 9A. However, the pattern of the first stopper insulating layer 41 of this embodiment is different from the pattern of the first stopper insulating layer 41 of the first embodiment.

Next, as shown in FIG. 9B, the first interlayer insulating layer 43 is formed by the step identical to the step of FIG. 6D of the first embodiment.

Next, as shown in FIG. 9C, planarization processing is carried out by the step identical to the step of FIG. 6E of the first embodiment. By this planarization processing, the silicon nitride layer 83 is removed, and the thickness of the first stopper insulating layer 41, thickness of the first interlayer insulating layer 43, and thickness of the silicon oxide layer 82 are reduced.

Next, after carrying out the steps identical to the steps of FIGS. 6F to 6M of the first embodiment, contact holes 61a to 61g are formed by the step identical to the step of FIG. 6N of the first embodiment as shown in FIG. 9D. However, the pattern of the second stopper insulating layer 51 of this embodiment is different from the pattern of the second stopper insulating layer 51 of the first embodiment. That is, the extension portion 51b of the second stopper insulating layer 51 extending to a part above the first end E1 is terminated at the midway position between the positions at which, from among the contact holes 61a to 61d to be provided so as to respectively correspond to the first conductive layers 21a, only the contact hole 61c and contact hole 61d are formed, and does not extend to the position at which the contact hole 61c is to be formed.

Each of FIGS. 10A to 10C is a cross-sectional view schematically showing a forming method of the contact holes 61a to 61g. It is to be noted that in each of FIGS. 10A to 10C, only the contact holes 61c and 61d are shown.

First, as shown in FIG. 10A, the contact holes 61c1 and 61d1 are respectively formed up to the midway position of the first stopper insulating layer 41 and midway position of the second stopper insulating layer 51.

Subsequently, as shown in FIG. 10B, the contact holes 61c2 and 61d2 are respectively formed up to the midway position of the first lower insulating layer 42 and midway position of the second lower insulating layer 52.

Thereafter, as shown in FIG. 100, the contact holes 61c and 61d are respectively formed in such a manner as to reach the corresponding first conductive layers 21a, whereby, as shown in FIG. 9D, the contact holes 61a to 61g are formed.

After the step of FIG. 9D, the contact holes 61a to 61g are filled with a metallic material, whereby the contacts 60a to 60g shown in FIG. 8 are formed.

As described above, in this embodiment too, the second stopper insulating layer 51 includes the extension portion 51b. Further, among the contacts 60a to 60d to be respectively connected to the corresponding first conductive layers 21a, the contact 60d penetrates through the extension portion 51b of the second stopper insulating layer 51 and first stopper insulating layer 41 to thereby be connected to the corresponding first conductive layer 21a. Owing to such a configuration, in this embodiment too, it becomes possible to appropriately form the contacts 60a to 60g as will be described below.

In this embodiment, when the etch back processing is carried out in the step of FIG. 9C, the part of the first stopper insulating layer 41 positioned on the uppermost layer side (part positioned on the terrace of the uppermost step of the first stacked portion 20a) is also etched, whereby the thickness of the first stopper insulating layer 41 is reduced at this part. For this reason, the thickness of the vicinity of the part of the first stopper insulating layer 41 at which the contact 60d penetrates through is reduced.

Assuming here that the second stopper insulating layer 51 includes no extension portion 51b, when the contact hole 61d is formed, only the part of the first stopper insulating layer 41 having the reduced thickness is used as the etching stopper, and thus there is a possibility of the first stopper insulating layer 41 becoming unable to sufficiently fulfill the function as the etching stopper.

In this embodiment, the second stopper insulating layer 51 includes the extension portion 51b, and hence when the contact holes 61a to 61g are formed in the step of FIG. 9D, this extension portion 51b sufficiently fulfills the function as the etching stopper. Besides, although when the contact hole 61d is formed, further the first stopper insulating layer 41 is etched in addition to the extension portion 51b of the second stopper insulating layer 51, the thickness of the first stopper insulating layer 41 is already reduced, and hence it is possible to etch the first stopper insulating layer 41 relatively easily.

Accordingly, in this embodiment too, it is possible to appropriately form the contacts 60a to 60g.

It is to be noted that although in the first and second embodiments described above, in the cross section of each of FIG. 3 and FIG. 8, each step is constituted of one conductive layer 21 and one insulating layer 22, each step may also be provided with two or more conductive layers 21 and two or more insulating layers 22. In this case, it is sufficient if, for example, a step constituted of one conductive layer 21 and one insulating layer 22 is formed in the Y-direction of FIG. 3 and FIG. 8. Further, the peripheral circuit region 300 shown in FIG. 1 may also be arranged in such a manner that when viewed from the Z-direction, the peripheral circuit region 300 overlaps the memory region 100 and stairs region 200 between the memory region 100, stairs region 200, and semiconductor substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a stacked layer body including a first stacked portion in which a plurality of first conductive layers are stacked to be apart from each other in a first direction, and which includes a stair-like first end, and a second stacked portion which is provided on an upper layer side of the first stacked portion, in which a plurality of second conductive layers are stacked to be apart from each other in the first direction, and which includes a stair-like second end;
a plurality of pillar structures each of which includes a semiconductor layer extending in the first direction in the stacked layer body;
a first stopper insulating layer covering at least a part of the first end;
a second stopper insulating layer including a cover portion covering the second end and an extension portion extending from the cover portion, and being apart from the first stopper insulating layer; and
a first contact penetrating through the extension portion of the second stopper insulating layer and being connected to a corresponding one of the first conductive layers.

2. The device of claim 1, further comprising a second contact penetrating through the first stopper insulating layer without penetrating through the second stopper insulating layer, and being connected to a corresponding one of the first conductive layers.

3. The device of claim 1, wherein
the first contact is connected to the correspond one of the first conductive layers without penetrating through the first stopper insulating layer.

4. The device of claim 2, wherein
the first contact penetrates through the first stopper insulating layer, and is connected to the corresponding one of the first conductive layers.

5. The device of claim 4, wherein
the first stopper insulating layer has a thickness at a part through which the first contact penetrates, which is less than a thickness at a part through which the second contact penetrates.

6. The device of claim 1, wherein
each of the first and second stopper insulating layers contains silicon and nitrogen.

7. The device of claim 1, further comprising a first lower insulating layer provided between the first stacked portion and the first stopper insulating layer, and formed of a material different from a material of the first and second stopper insulating layers, wherein
the first contact penetrates through the first lower insulating layer.

8. The device of claim 1, further comprising a second lower insulating layer formed of a material different from a material of the first and second stopper insulating layers, the second lower insulating layer including a first portion provided between the second stacked portion and the cover portion of the second stopper insulating layer and a second portion extending from the first portion to an area under the extension portion of the second stopper insulating layer, wherein
the first contact penetrates through the second portion of the second lower insulating layer.

9. The device of claim 1, wherein
the stacked layer body further includes an intermediate portion formed of a material different from a material of the first and second stopper insulating layers,
the intermediate portion includes a first portion provided between the first stacked portion and the second stacked portion, and a second portion extending from the first portion to an area under the extension portion of the second stopper insulating layer, and
the first contact penetrates through the second portion of the intermediate portion.

10. The device of claim 2, further comprising:
a first interlayer insulating layer covering at least a part of the first stopper insulating layer, and being formed of a material different from a material of the first and second stopper insulating layers; and
a second interlayer insulating layer covering the second stopper insulating layer, and being formed of a material different from the material of the first and second stopper insulating layers, wherein
the second contact penetrates through the first and second interlayer insulating layers.

11. The device of claim 1, further comprising a third contact penetrating through the second stopper insulating layer, and being connected to a corresponding one of the second conductive layers.

12. The device of claim 11, further comprising:
a first interlayer insulating layer covering at least a part of the first stopper insulating layer, and being formed of a material different from a material of the first and second stopper insulating layers; and
a second interlayer insulating layer covering the second stopper insulating layer, and being formed of a material different from the material of the first and second stopper insulating layers, wherein
the third contact penetrates through the second interlayer insulating layer.

13. The device of claim 11, further comprising a second lower insulating layer formed of a material different from a material of the first and second stopper insulating layers, the second lower insulating layer including a first portion provided between the second stacked portion and the cover portion of the second stopper insulating layer and a second portion extending from the first portion to an area under the extension portion of the second stopper insulating layer, wherein
the third contact penetrates through the first portion of the second lower insulating layer.

14. The device of claim 1, wherein
the first stacked portion includes the plurality of first conductive layers and a plurality of first insulating layers alternately stacked in the first direction, and
the second stacked portion includes the plurality of second conductive layers and a plurality of second insulating layers alternately stacked in the first direction.

15. The device of claim 14, wherein
the stacked layer body further includes an intermediate insulating layer provided between the first stacked portion and the second stacked portion, and
a thickness of the intermediate insulating layer is greater than a thickness of each of the plurality of first insulating layers and a thickness of each of the plurality of second insulating layers.

16. A semiconductor device comprising:
a stacked layer body including a first stacked portion in which a plurality of first conductive layers are stacked to be apart from each other in a first direction, and which includes a stair-like first end, and a second stacked portion which is provided on an upper layer side of the first stacked portion, in which a plurality of second conductive layers are stacked to be apart from each other in the first direction, and which includes a stair-like second end;
a plurality of pillar structures each of which includes a semiconductor layer extending in the first direction in the stacked layer body;
a first insulating layer covering at least a part of the first end;
a second insulating layer including a cover portion covering the second end and an extension portion extending from the cover portion, and being apart from the first insulating layer;
a third insulating layer covering an area above the first insulating layer and the second insulating layer; and
a first contact penetrating through the extension portion of the second insulating layer and the third insulating layer and being connected to a corresponding one of the first conductive layers, wherein
a material of the first insulating layer and a material of the third insulating layer are different from each other, and a material of the second insulating layer and the material of the third insulating layer are different from each other.

17. The device of claim 16, wherein
the first contact is connected to the corresponding one of the first conductive layers without penetrating through the first insulating layer.

18. The device of claim 16, wherein
the first contact penetrates through the first insulating layer and is connected to the corresponding one of the first conductive layers.

19. The device of claim 16, wherein
each of the first and second insulating layers contains silicon and nitrogen, and the third insulating layer contains silicon and oxygen.

20. The device of claim 16, wherein
the stacked layer body further includes a fourth insulating layer provided between the first stacked portion and the second stacked portion,
the first stacked portion includes the plurality of first conductive layers and a plurality of fifth insulating layers alternately stacked in the first direction,
the second stacked portion includes the plurality of second conductive layers and a plurality of sixth insulating layers alternately stacked in the first direction, and
a thickness of the fourth insulating layer is greater than a thickness of each of the plurality of fifth insulating layers and a thickness of each of the plurality of sixth insulating layers.
